(19) United States
(12) Patent Application Publication
(10) Pub. No.: US 2018/0076148 A1
(43) Pub. Date: Mar. 15, 2018

(54) THROUGH-MOLD FEATURES FOR SHIELDING APPLICATIONS

(71) Applicant: SKYWORKS SOLUTIONS, INC., Woburn, MA (US)

(72) Inventors: Hoang Mong NGUYEN, Fountain Valley, CA (US); Anthony James LOBIANCO, Irvine, CA (US)

(21) Appl. No.: 15/705,230

(22) Filed: Sep. 14, 2017

Related U.S. Application Data
(60) Provisional application No. 62/394,885, filed on Sep. 15, 2016.

(51) Int. Cl. H01L 23/552; H01L 21/56; H01L 23/498; H01L 23/31; H01L 23/48; H01L 21/768; H01L 21/78

(52) U.S. Cl. CPC H01L 23/552; H01L 21/561; H01L 23/49838; H01L 23/49811; H01L 21/78; H01L 23/481; H01L 21/565; H01L 21/76802; H01L 21/76877; H01L 23/3121

(57) ABSTRACT

Through-mold features for shielding applications. In some embodiments, a packaged module can include a packaging substrate having a ground plane, and one or more contact pads implemented on an upper side and electrically connected to the ground plane. The module can further include a radio-frequency circuit assembly implemented on the upper side of the packaging substrate, and an overmold implemented on the upper side of the packaging substrate to cover the one or more contact pads and the radio-frequency circuit assembly. The module can further include a conductive layer configured to cover an upper surface of the overmold and one or more through-mold features, with each being configured to provide an electrical connection between the conductive layer and the ground plane through the corresponding contact pad, to thereby provide shielding between a first location within the module and a second location relative to the module.

### CROSS-REFERENCE TO RELATED APPLICATION(S)

This application claims priority to U.S. Provisional Application No. 62/394,885 filed Sep. 15, 2016, entitled THROUGH-MOLD VIAS FOR RADIO-FREQUENCY SHIELDING APPLICATIONS, the disclosure of which is hereby expressly incorporated by reference herein in its respective entirety.

### BACKGROUND

### Field

The present disclosure relates to packaged electronic modules having electromagnetic shielding functionality.

### Description of the Related Art

A packaged electronic module typically includes a packaging substrate and a number of components mounted thereon. Such components can include, for example, one or more semiconductor die each having an integrated circuit, and one or more passive components that typically facilitate various functionalities associated with the integrated circuit(s) of the semiconductor die.

The foregoing packaged module typically also includes a mold structure implemented over the packaging substrate to encapsulate the mounted components. Such a mold structure can provide protection for the components, and facilitate handling of the packaged module.

### SUMMARY

In accordance with some implementations, the present disclosure relates to a shielded radio-frequency module that includes a packaging substrate having an upper side, a lower side, a ground plane, and one or more contact pads implemented on the upper side and electrically connected to the ground plane. The shielded radio-frequency module further includes a radio-frequency circuit assembly implemented on either or both of the upper and lower sides of the packaging substrate, and an overmold implemented at least on the upper side of the packaging substrate to cover the one or more contact pads and some or all of the radio-frequency circuit assembly. The overmold defines an upper surface. The shielded radio-frequency module further includes a conductive layer configured to cover some or all of the upper surface of the overmold, and one or more through-mold features, each being configured to provide an electrical connection between the conductive layer and the ground plane through the corresponding contact pad, to thereby provide shielding between a first location within the radio-frequency module and a second location relative to the radio-frequency module.

In some embodiments, the one or more through-mold features can include one or more through-mold vias, one or more through-mold trenches, or any combination thereof. In some embodiments, the one or more through-mold vias can include a plurality of through-mold vias implemented to laterally around some or all of the radio-frequency circuit assembly. The plurality of through-mold vias can be configured to provide shielding between the first location and the second location that is external to the radio-frequency module.

In some embodiments, the shielding provided by the one or more through-mold vias can include intra-module shielding between the first location and the second location that is also within the radio-frequency module. In some embodiments, the one or more through-mold vias can be configured and arranged to replace one or more shielding wirebonds that provide similar shielding functionality.

In some embodiments, the conductive layer can be configured to cover substantially all of the upper surface of the overmold. The radio-frequency module can have a rectangular shaped footprint such that the upper surface of the overmold joins with four side walls defined by the radio-frequency module. The conductive layer can further cover at least some of each of the four side walls of the radio-frequency module. The packaging substrate can further include a contact feature electrically connected to the ground plane and exposed on each of the four side walls, such that the conductive layer on the corresponding side wall is further electrically connected to the ground plane through the contact feature. The conductive layer covering the upper surface of the overmold and the four side walls of the radio-frequency module can be implemented as a conformal coating of conductive material.

In some embodiments, each of the one or more through-mold vias can be an opening that extends from the upper surface of the overmold to the corresponding contact pad on the packaging substrate. The electrical connection provided by the through-mold via can include a conductive material that partially or fully fills the opening to electrically connect the conductive layer and the corresponding contact pad. The conductive material can include, for example, a metal that fills substantially all of the opening, a solder ball inserted into the opening, or a portion of the conductive layer on the upper surface of the overmold extending into the opening to cover at least a portion of a side wall of the opening and at least a portion of the contact pad. The conductive layer covering the upper surface of the overmold and the opening can include a conformal coating of conductive material.

In some embodiments, the shielded radio-frequency module can further include a solder feature implemented over each of the one or more contact pads to raise a bottom portion of the corresponding through-mold via away from the contact pad.

In some embodiments, the radio-frequency circuit assembly can be implemented on the upper side of the packaging substrate. In some embodiments, the radio-frequency circuit assembly can be implemented on both of the upper side and the lower side of the packaging substrate. The portion of the radio-frequency circuit assembly implemented on the lower side of the packaging substrate can include one or more die mounted to the lower side of the packaging substrate. In some embodiments, the shielded radio-frequency module can further include a ball grid array implemented on the lower side of the packaging substrate to define an underside volume to accommodate the one or more die mounted to the lower side of the packaging substrate.

According to some teachings, the present disclosure relates to a method for manufacturing a plurality of shielded radio-frequency modules. The method includes providing or forming a packaging substrate panel having a plurality of units, with each unit having an upper side, a lower side, a ground plane, and one or more contact pads implemented on the upper side and electrically connected to the ground plane. The method further includes implementing a radio-frequency circuit assembly for each unit on either or both of the upper and lower sides of the packaging substrate panel. The method further includes forming an overmold on at least the upper side of the packaging substrate panel to cover the one or more contact pads and some or all of the radio-frequency circuit assembly of each unit, with the overmold defining an upper surface. The method further includes forming one or more openings through the overmold to expose at least a portion of each of the corresponding one or more contact pads, with each opening being configured to facilitate an electrical connection between the upper surface of the overmold and the corresponding contact pad.

In some embodiments, forming of the one or more openings through the overmold can include one or more vias, one or more trenches, or any combination thereof. In some embodiments, the method can further include forming a conductive layer on the upper surface of the overmold. In some embodiments, the method can further include forming an electrical connection between the conductive layer on the upper surface of the overmold and the one or more contact pads through the one or more openings. In some embodiments, the forming of the conductive layer on the upper surface of the overmold and the forming of the electrical connection through each of the one or more openings can be performed in a single step. In some embodiments, the single step can include, for example, a physical vapor deposition process. In some embodiments, the method can further include singulating the packaging substrate panel and the overmold thereon to generate a plurality of individual shielded radio-frequency modules associated with the plurality of units.

In some embodiments, the method can further include singulating the packaging substrate panel and the overmold thereon to generate a plurality of individual unshielded radio-frequency modules associated with the plurality of units. In some embodiments, the method can further include processing the plurality of individual unshielded radio-frequency modules to generate a plurality of individual shielded radio-frequency modules. The processing of the plurality of individual unshielded radio-frequency modules can include holding the plurality of individual unshielded radio-frequency modules in a manner that exposes the upper surface and side walls of each unshielded radio-frequency module. The processing of the plurality of individual unshielded radio-frequency modules can further include performing a deposition operation to form a conformal conductive layer on the upper surface and side walls of each radio-frequency module. The performing of the deposition operation can further include forming a conformal conductive layer on a surface of each opening to provide the electrical connection associated with the opening.

In some implementations, the present disclosure relates to a wireless device that includes a circuit board configured to receive a plurality of components, a transceiver implemented on the circuit board and configured to process radio-frequency signals, and a shielded radio-frequency module implemented on the circuit board and in communication with the transceiver. The shielded radio-frequency module includes a packaging substrate having an upper side, a lower side, a ground plane, and one or more contact pads implemented on the upper side and electrically connected to the ground plane. The shielded radio-frequency module further includes a radio-frequency circuit assembly implemented on either or both of the upper and lower sides of the packaging substrate, and an overmold implemented at least on the upper side of the packaging substrate to cover the at least one contact pad and some or all of the radio-frequency circuit assembly, with the overmold defining an upper surface. The shielded radio-frequency module further includes a conductive layer configured to cover some or all of the upper surface of the overmold, and one or more through-mold features, with each being configured to provide an electrical connection between the conductive layer and the ground plane through the corresponding contact pad, to thereby provide shielding between a first location within the radio-frequency module and a second location relative to the radio-frequency module.

In some embodiments, the one or more through-mold features can include one or more vias, one or more trenches, of any combination thereof.

For purposes of summarizing the disclosure, certain aspects, advantages and novel features of the inventions have been described herein. It is to be understood that not necessarily all such advantages may be achieved in accordance with any particular embodiment of the invention. Thus, the invention may be embodied or carried out in a manner that achieves or optimizes one advantage or group of advantages as taught herein without necessarily achieving other advantages as may be taught or suggested herein.

### BRIEF DESCRIPTION OF THE DRAWINGS

FIG. 1 depicts a packaged radio-frequency (RF) module having a shielding functionality.

FIG. 2 shows an example of a shielded RF module.

FIG. 3 shows another example of a shielded RF module.

FIG. 4 shows yet another example of a shielded RF module.

FIG. 5 depicts a packaged RF module having shielding functionality facilitated by an electrical connection associated with a through-mold feature such as a through-mold via (TMV) or a through-mold trench.

FIG. 6A shows that in some embodiments, a TMV can have a rectangular (e.g., square) sectional shape implemented through an overmold.

FIG. 6B shows that in some embodiments, a TMV can have a round (e.g., circular) sectional shape implemented through an overmold.

FIG. 6C shows that in some embodiments, a through-mold trench can be implemented between first and second regions of a packaged RF module.

FIG. 6D shows that in some embodiments, a through-mold trench can be configured to extend substantially fully between opposing edges of an overmold of a packaged RF module.

FIG. 7 shows that in some embodiments, a packaged RF module having one or more features as described herein can have a plurality of conductive TMVs implemented through an overmold to partially or fully surround a region associated with an RF circuit assembly.

FIG. 8 shows a side sectional view of an example TMV formed through an overmold.

FIG. 9 shows a side sectional view of another example TMV formed through an overmold.

FIG. 10A shows that in some embodiments, a conductive structure such as a solder block can be provided on a contact pad and be dimensioned to raise the floor of a TMV formed partially through an overmold.

FIG. 10B shows a side sectional view of another example TMV formed through an overmold, and such a TMV can dimensioned to receive a conductive structure such as a solder ball.

FIGS. 11A-11F show various example stages of a fabrication process that can be utilized to manufacture a plurality of shielded RF modules that do not have conductive side-wall layers.

FIGS. 12A-12F show various example stages of a fabrication process that can be utilized to manufacture a plurality of shielded RF modules that have conductive side walls.

FIG. 13 shows an example process that can be implemented to manufacture the example shielded RF modules of FIGS. 11A-11F.

FIG. 14 shows an example process that can be implemented to manufacture the example shielded RF modules of FIGS. 12A-12F.

FIG. 15 depicts an example wireless device having one or more advantageous features described herein.

### DETAILED DESCRIPTION OF SOME EMBODIMENTS

The headings provided herein, if any, are for convenience only and do not necessarily affect the scope or meaning of the claimed invention.

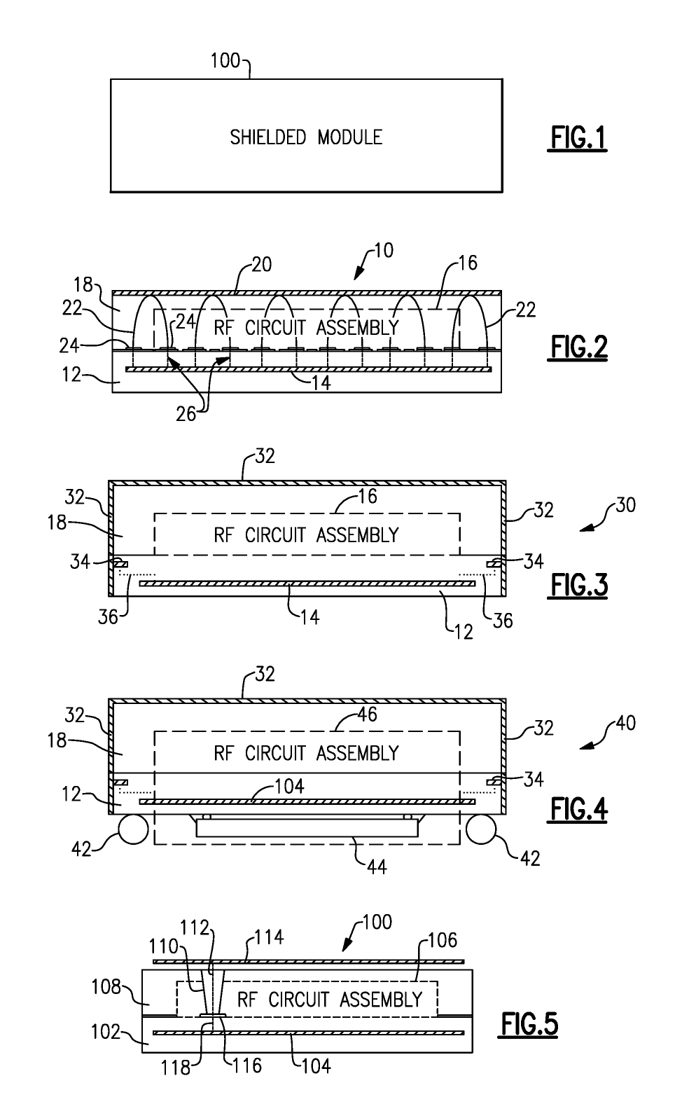

FIG. 1 depicts a packaged radio-frequency (RF) module 100 having a shielding functionality. As described herein, such a packaged module can include one or more through-mold features configured to facilitate the shielding functionality. In some embodiments, such one or more through-mold features can include one or more through-mold vias (TMVs), one or more through-mold trenches, or any combination thereof. It will be understood that a packaged module having one or more features as described herein can also utilize one or more through-mold features other than via(s) and trench(es).

FIGS. 2-4 show some examples of packaged RF modules having shielding functionalities. For example, FIG. 2 shows a shielded RF module 10 having a packaging substrate 12 and an RF circuit assembly 16 implemented on the packaging substrate 12. Such an RF circuit assembly can include, for example, integrated circuits (e.g., power amplifiers, switching circuits, front-end circuits, low-noise amplifiers, etc.) implemented on one or more semiconductor die, passive devices, etc.

The shielded module 10 is shown to further include an overmold structure 16 implemented to substantially encapsulate the RF circuit assembly 16. For such an overmolded module, RF shielding functionality can be provided by a plurality of shielding wirebonds 22 arranged relative to one or more portions of the RF circuit assembly 16 to provide shielding between different locations within the module 10 (also referred to as intra-module shielding), between a location within the module 10 and a location external to the module 10, or any combination thereof. Typically, such shielding wirebonds are formed on the packaging substrate 12, and then the overmold 16 is formed to generally encapsulate the shielding wirebonds 22 (as well as the RF circuit assembly 16).

In the example of FIG. 2, the shielding wirebonds 22 can have their upper portions electrically connected to a conductive layer 20 (e.g., implemented on the upper surface of the overmold 18), and their lower portions electrically connected to respective contact pads 24 (e.g., implemented on the upper surface of the packaging substrate 12). The contact pads 24 are shown to be electrically connected (indicated as 26) to a ground plane 14 within the packaging substrate 12. Accordingly, the conductive layer 20 is electrically connected to the ground plane 14 through the shielding wirebonds 22. Thus, the conductive layer 20, the shielding wirebonds 22, and the ground plane 14 can combine to provide the foregoing RF shielding functionality.

In the example of FIG. 2, a plurality of the shielded modules 10 can be fabricated together while attached to each other in a panel format. In such a panel-based fabrication technique, the formation of the conductive layer 20 can be the last step or close to the last step prior to a singulation step. Such a singulation step can separate the plurality of shielded modules 10 into individual shielded modules 10.

Examples related to such shielding wirebonds can be found in, for example, U.S. Pat. No. 9,071,335, entitled RADIO-FREQUENCY MODULES HAVING TUNED SHIELDING-WIREBONDS, the disclosure of which is hereby incorporated by reference herein in its entirety and to be considered part of the specification of the present application.

FIG. 3 shows another example of a shielded RF module 30 in which a conductive layer 32 on the upper surface of an overmold 18 is electrically connected to a ground plane 14 that is within a packaging substrate 12. In such a shielded RF module, an RF circuit assembly 16 can be implemented on the packaging substrate 12 in a manner similar to the example of FIG. 2.

In the example of FIG. 3, the conductive layer on the upper surface of the overmold 18 can be electrically connected to the ground plane 14 through a conductive layer 32 on each of one or more of side walls of the module 30. For the purpose of description, it will be assumed that all four side walls of a rectangular shaped module have respective conductive layers. In some embodiments, such conductive layers on the side walls of the module can be formed together with the conductive layer on the upper surface of the overmold as a conformal layer utilizing, for example, a deposition process such as a physical vapor deposition (PVD) process. Accordingly, the conductive layers on the upper surface of the overmold 18 and the side walls of the module 30 are indicated as 32.

Referring to FIG. 3, the side-wall conductive layers 32 are shown to be electrically connected to the ground plane 14 through conductive features 34 implemented in the packaging substrate 12 and exposed on the respective side walls of the packaging substrate 12 (to form electrical connections with the respective side-wall conductive layers 32), and through internal electrical connections (indicated as 36).

In the example of FIG. 3, a plurality of the shielded modules 30 can be partially fabricated together while attached to each other in a panel format. In such a panel-based fabrication technique, the formation of the overmold 18 can be achieved while in the panel format. However, since the side walls of each module need to be exposed to allow formation of the side-wall conductive layers 32, such formation of the conformal conductive layer for the module (e.g., including the upper layer and the side-wall layers) can be implemented after unshielded modules are singulated.

Examples related to such conformal shielding of modules can be found in, for example, U.S. Publication No. 2017/0221836, entitled SPUTTERING SYSTEMS AND METHODS FOR PACKAGING APPLICATIONS, the disclosure of which is hereby incorporated by reference herein in its entirety and to be considered part of the specification of the present application.

FIG. 4 shows another example of a shielded RF module 40 in which a conductive layer 32 on the upper surface of an overmold 18 is electrically connected to a ground plane 14 that is within a packaging substrate 12, in a manner similar to the example of FIG. 3. In such a shielded RF module, an RF circuit assembly 46 can be implemented on the packaging substrate 12, as well as under the packaging substrate 12. Accordingly, the RF circuit assembly 46 can include one or more devices such as die and/or passive devices (indicated as 44) mounted under the packaging substrate 12. In some embodiments, such under-mounted device(s) 44 can occupy a volume defined by the underside of the packaging substrate 12 and a plurality of contact features such as a ball grid array (BGA)

In the example of FIG. 4, the conductive layer 32 can be configured similar to the example of FIG. 3. Examples related to such conformal shielding of dual-sided BGA-based modules can be found in the above-mentioned U.S. Publication No. 2017/0221836.

In some embodiments, a shielded RF module can include one or more through-mold features implemented to facilitate at least some of the module's shielding functionality. In some embodiments, such one or more through-mold features can include one or more through-mold vias (TMVs), one or more through-mold trenches, or any combination thereof. In some embodiment, and as described herein, such one or more through-mold features can be implemented instead of shielding wirebonds to provide shielding functionalities similar to those provided by shielding wirebonds. In some embodiment, the one or more through-mold features as described herein can be implemented with one or more shielding wirebonds and/or other shielding feature(s) to provide shielding functionalities. As also described herein, such one or more through-mold features can also be implemented with conformal shielding techniques. For example, a conductive layer applied in a conformal manner can provide a conductive path through a given through-mold feature; thus, such conformal coated through-mold feature can provide shielding functionality similar to that of a shielding wirebond.

In such an example, side walls of a given module may or may not be conformally coated. If the side walls are not coated (e.g. similar to the wirebond shielding example of FIG. 2), most if not all of various process steps can be performed while an array of modules are in a panel format, and singulation can be achieved as a last (or close to the last) step. If the side walls are coated (e.g., similar to the examples of FIGS. 3 and 4), the coated through-mold feature(s) can be utilized in conjunction with the coated side wall to, for example, provide a global shielding for the module (e.g., by the conformal coating on the upper surface and the side walls), as well as intra-module shielding (e.g., by the coated through-mold feature(s), to provide shielding between two locations within the module). Examples related to both of the foregoing examples are described herein in greater detail.

In some embodiments, and as also described herein, a through-mold feature can also facilitate an electrical connection without having a conformal coating of conductive material. For example, a conductive feature such as a solder structure can be inserted into the through-mold feature, and such a conductive feature can provide an electrical connection between upper and lower portions of the through-mold feature. Examples related to such electrical connections are described herein in greater detail.

FIG. 5 depicts a packaged RF module 100 having shielding functionality facilitated by an electrical connection (indicated as 112) associated with a through-mold feature 110. As described herein, such an electrical connection can be implemented in a number of different ways; accordingly, in the example of FIG. 5, the electrical connection is depicted by a dashed line 112.

In the example of FIG. 5, an upper conductive layer 114 is shown to be implemented over an overmold 108 that can partially or fully encapsulate an RF circuit assembly 106. Such an RF circuit assembly is shown to be implemented on a packaging substrate 102 that includes a ground plane 104.

In the example of FIG. 5, a contact pad 116 is shown to be implemented on the surface of the packaging substrate 102 so as to facilitate the electrical connection 112 associated with the through-mold feature 110. The contact pad 116 is shown to be electrically connected (indicated as 118) to the ground plane 104. Thus, the electrical connection 112 associated with the through-mold feature 110 electrically connects the upper conductive layer 114 with the ground plane 104, thereby providing an RF shielding functionality.

In the example of FIG. 5, the upper conductive layer 114 can be similar to any one of the various examples described herein, including those associated with the examples of FIGS. 2-4. Further, such an upper conductive layer can be part of a conformal coating that may or may not include conductive layers of the side wall(s) of the module.

In the example of FIG. 5, the packaged RF module 100 is depicted as having the RF circuit assembly 106 on the upper side of the packaging substrate 102. However, it will be understood that a packaged RF module having one or more through-mold feature-based electrical connections can also include one or more components under the packaging substrate 102, similar to the example of FIG. 4.

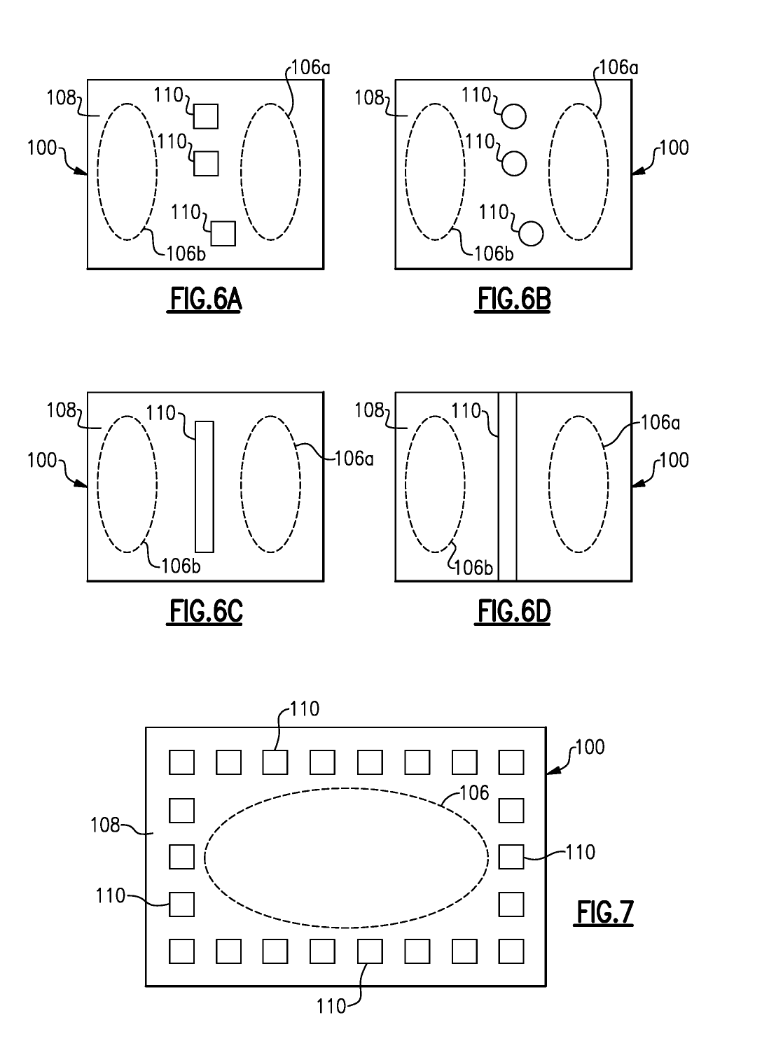

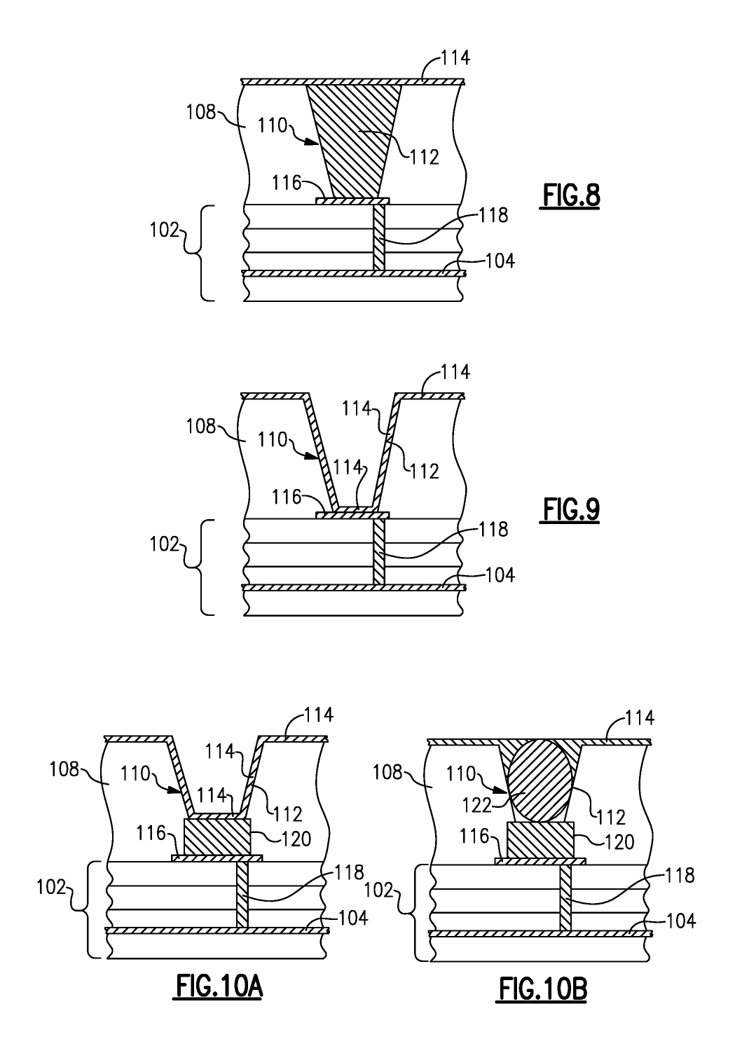

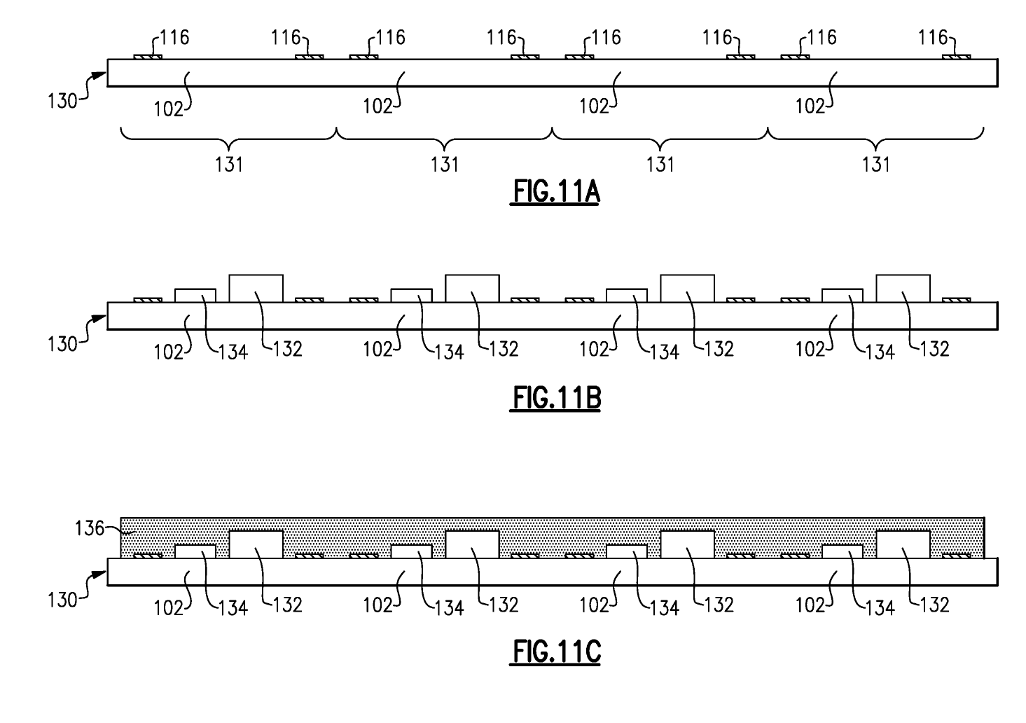

FIGS. 6A and 6B show, among others, that a through-mold via (TMV) 110 having one or more features as described herein can have different sectional shapes. For example, in FIG. 6A, each of a plurality of TMVs 110 is shown to have a rectangular (e.g., square) sectional shape implemented through an overmold 108. In another example, FIG. 6B shows that each of a plurality of TMVs 110 can have a round (e.g., circular) sectional shape implemented through an overmold 108. It will be understood that other shaped TMVs can also be implemented.

FIGS. 6A and 6B also show that in some embodiments, a packaged RF module 100 having one or more features as described herein can have one or more conductive TMVs 110 implemented to provide intra-module shielding functionality. For example, in each of FIGS. 6A and 6B, a plurality of conductive TMVs 110 are shown to be arranged so as to provide shielding between a first region 106a associated with an RF circuit assembly (e.g., 106 in FIG. 5) and a second region 106b associated with the RF circuit assembly.

FIGS. 6C and 6D show that in some embodiments, a packaged RF module 100 can include a through-mold trench 110 implemented through a corresponding overmold 108 and configured to provide shielding functionality similar to one or more TMVs. For example, the through-mold trench 110 in each of FIGS. 6C and 6D can be implemented to provide intra-module shielding functionality. More particularly, in each of FIGS. 6C and 6D, the respective through-mold trench 110 is shown to be configured to provide shielding between a first region 106a associated with an RF circuit assembly (e.g., 106 in FIG. 5) and a second region 106b associated with the RF circuit assembly.

In the examples of FIGS. 6C and 6D, a given through-mold trench 110 may extend partially or substantially fully between two edges (e.g., two opposing edges) of the corresponding overmold 108 of the packaged RF module 100. For example, in the example of FIG. 6C, the through mold trench 110 is shown to extend partially between two opposing edges of the overmold 108 and provide shielding between the first and second regions 106a, 106b. In another example, it may be desirable to have a through-mold trench extend fully between two opposing edges. In such a situation, and as shown in the example of FIG. 6D, the through mold trench 110 can extend substantially fully between two opposing edges of the overmold 108 and provide shielding between the first and second regions 106a, 106b.

In the examples of FIGS. 6C and 6D, the respective through-mold trenches are described as being configured to provide intra-module shielding functionality. It will be understood that in some embodiments, one or more through-mold trenches can also be implemented to provide shielding between a region within the module and a region external to the module, intra-module shielding, or any combination thereof.

Some examples are described herein in the context of through-mold vias (TMVs). However, it will be understood that similar systems, devices, structures and/or methods can also be implemented utilizing through-mold trenches. It will also be understood that in some embodiments, similar systems, devices, structures and/or methods can also be implemented utilizing combinations of TMVs and through-mold trenches.

FIG. 7 shows that in some embodiments, a packaged RF module 100 having one or more features as described herein can have a plurality of conductive TMVs 110 implemented through an overmold 108 to partially or fully surround a region 106 associated with an RF circuit assembly (e.g., 106 in FIG. 5). Such a configuration of the conductive TMVs 110 can provide shielding between the region 106 and one or more regions external to the module 100.

It will be understood that a packaged RF module having one or more features as described herein can have any combination of features of the examples of FIGS. 6 and 7.

FIGS. 8-10 show non-limiting examples of how an electrical connection can be implemented with use of a TMV. FIG. 8 shows a side sectional view of an example TMV 110 formed through an overmold 108. In some embodiments, such a TMV can be filled with a sufficient amount of conductive material to provide an electrical connection 112 between an upper conductive layer 114 (on the upper surface of the overmold 108) and a contact pad 116 (on the packaging substrate 102). Such a contact pad can be electrically connected to a ground plane 104 through, for example, one or more conductive vias 118 formed through one or more layers of the packaging substrate 102.

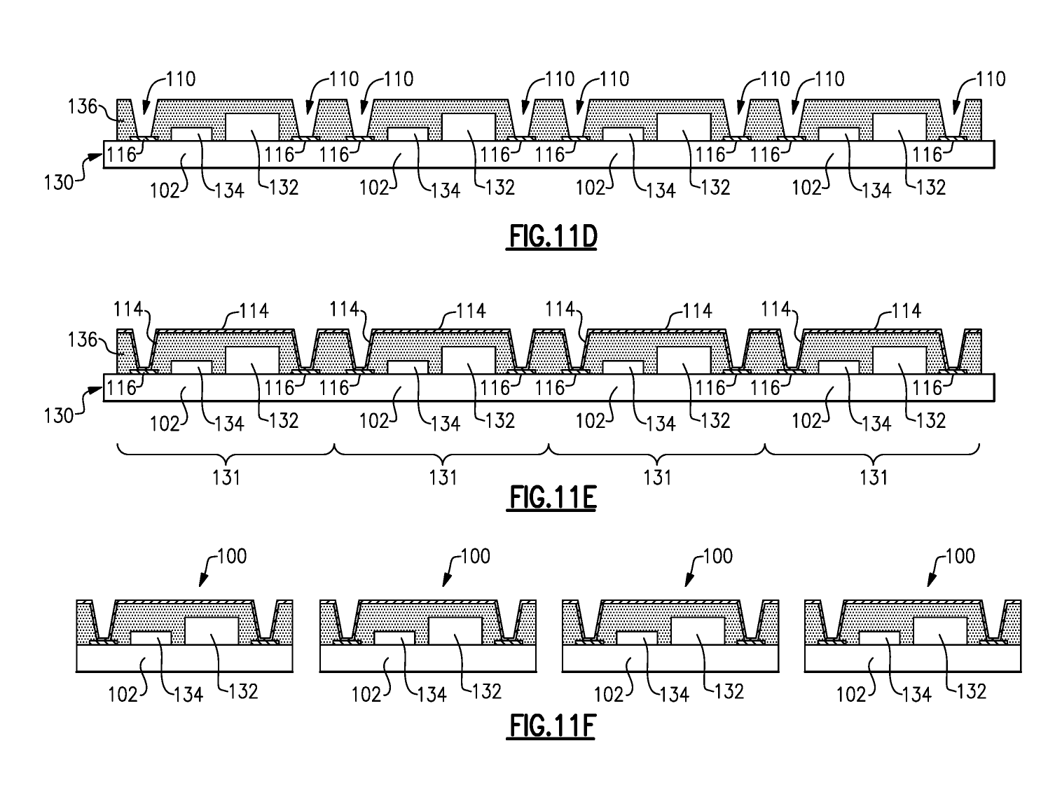

FIG. 9 shows a side sectional view of another example TMV 110 formed through an overmold 108. In some embodiments, such a TMV and an upper surface of the overmold 108 can be coated with conductive material so as to form a conformal conductive layer 114. Such a conformal conductive layer (114) can be electrically connected to a contact pad 116 (on the packaging substrate 102). Such a contact pad can be electrically connected to a ground plane 104 through, for example, one or more conductive vias 118 formed through one or more layers of the packaging substrate 102. Accordingly, the conformal conductive layer 114 formed on the surface of the TMV 110 functions as an electrical connection 112 between the upper conductive layer (also indicated as 114) and the contact pad 116 (and thus the ground plane 104).

FIG. 10A shows that in some embodiments, a conductive structure 120 such as a solder block can be provided on a contact pad 116 (on the packaging substrate 102). Such a solder block can be dimensioned to raise the floor of a TMV 110 formed partially through an overmold 108. Such a raised floor can allow the aspect ratio (e.g., ratio of average width to height) to be increased when compared to, for example, the TMV of FIG. 9. In some applications, such an increased aspect ratio of the TMV 110 can allow improved formation of, for example, a conformal coating 114 of conductive material on the surface of the TMV 110 for providing an electrical connection 112 associated with the TMV 110.

In the example of FIG. 10A, the conformal conductive layer 114 is depicted as covering both the surface of the TMV 110 as well as an upper surface of the overmold 108. Accordingly, the conformal conductive layer 114 on the upper surface of is electrically connected to the contact pad 116 through the solder block 120. The contact pad 116 can be electrically connected to a ground plane 104 through, for example, one or more conductive vias 118 formed through one or more layers of the packaging substrate 102.

FIG. 10B shows a side sectional view of another example TMV 110 formed through an overmold 108. In some embodiments, such a TMV can dimensioned to receive a conductive structure such as a solder ball 122. A bottom portion of the solder ball 122 can be in electrical contact with, for example, a solder block 120 which is in turn electrically connected to a contact pad 116. An upper portion of the solder ball 122 can be exposed so as to provide an electrical connection with a conductive layer 114 formed on an upper surface of the overmold 108. Thus, in the example of FIG. 10B, the solder ball 122 can provide an electrical connection 112 between the conductive layer 114 and the contact pad 116. Such a contact pad can be electrically connected to a ground plane 104 through, for example, one or more conductive vias 118 formed through one or more layers of the packaging substrate 102.

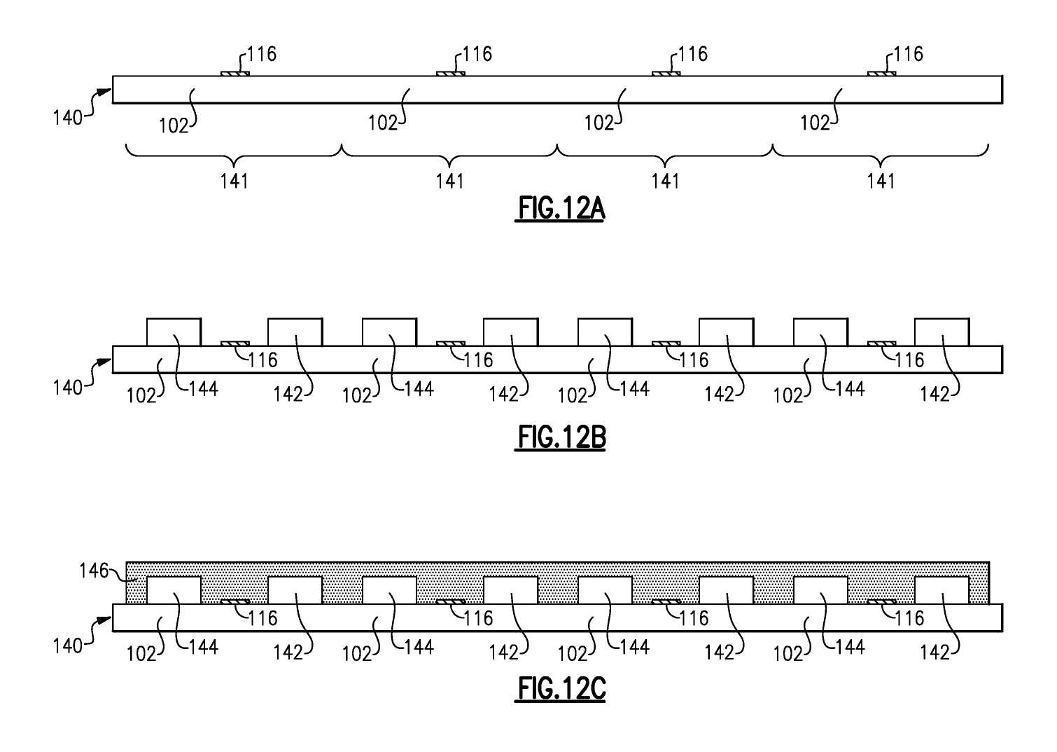

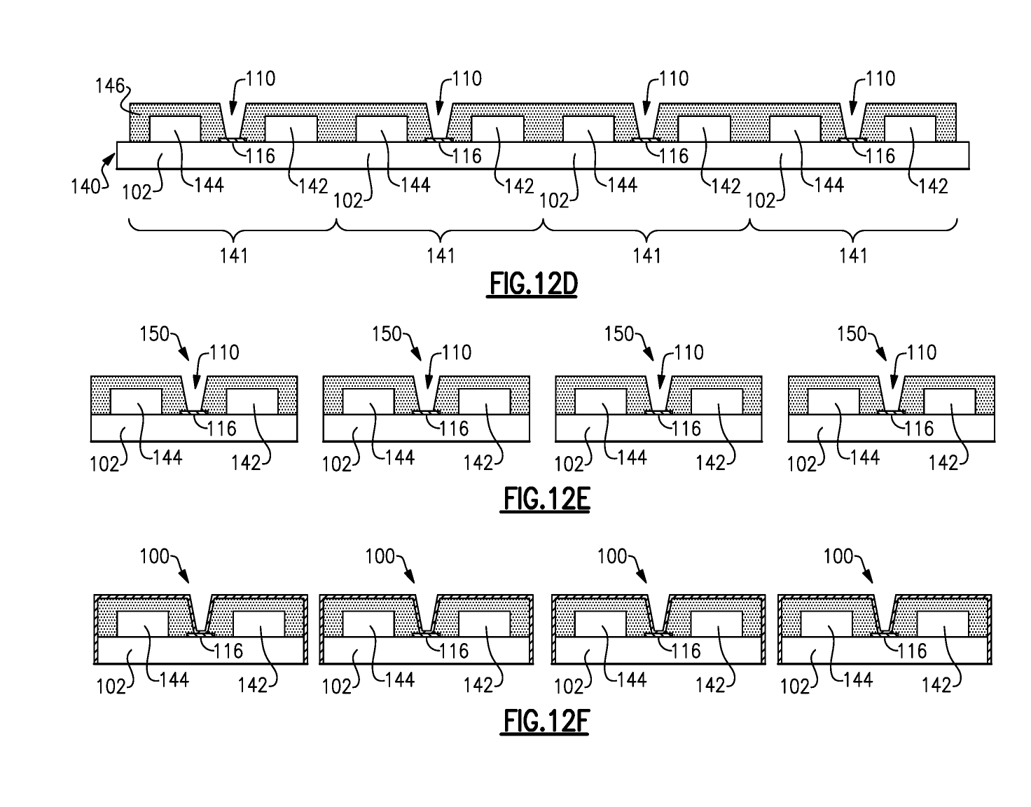

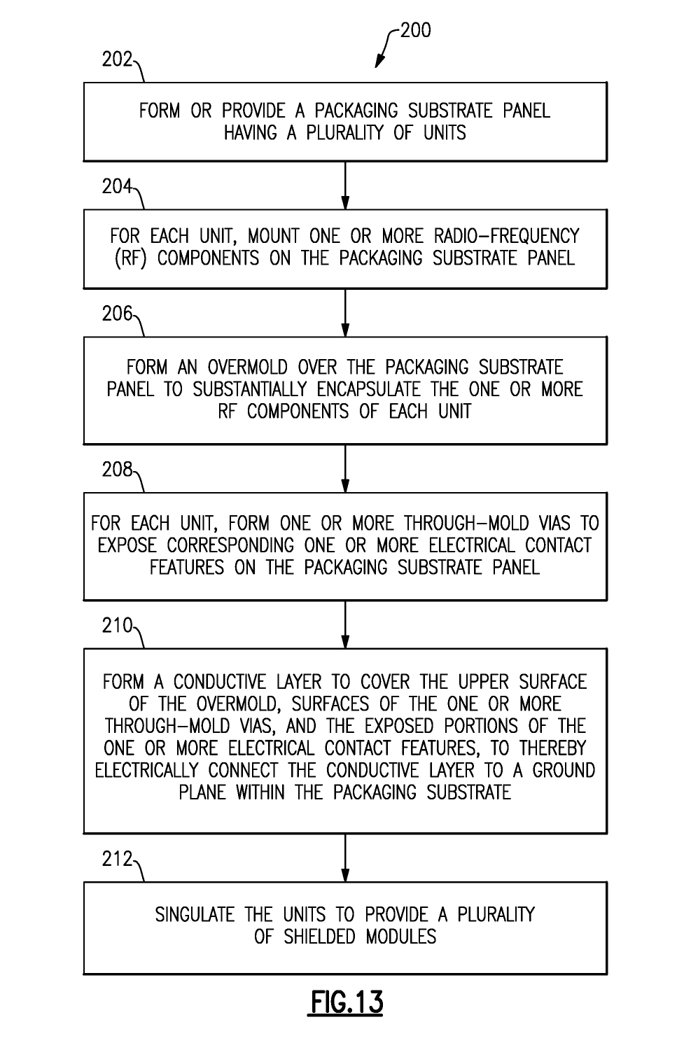

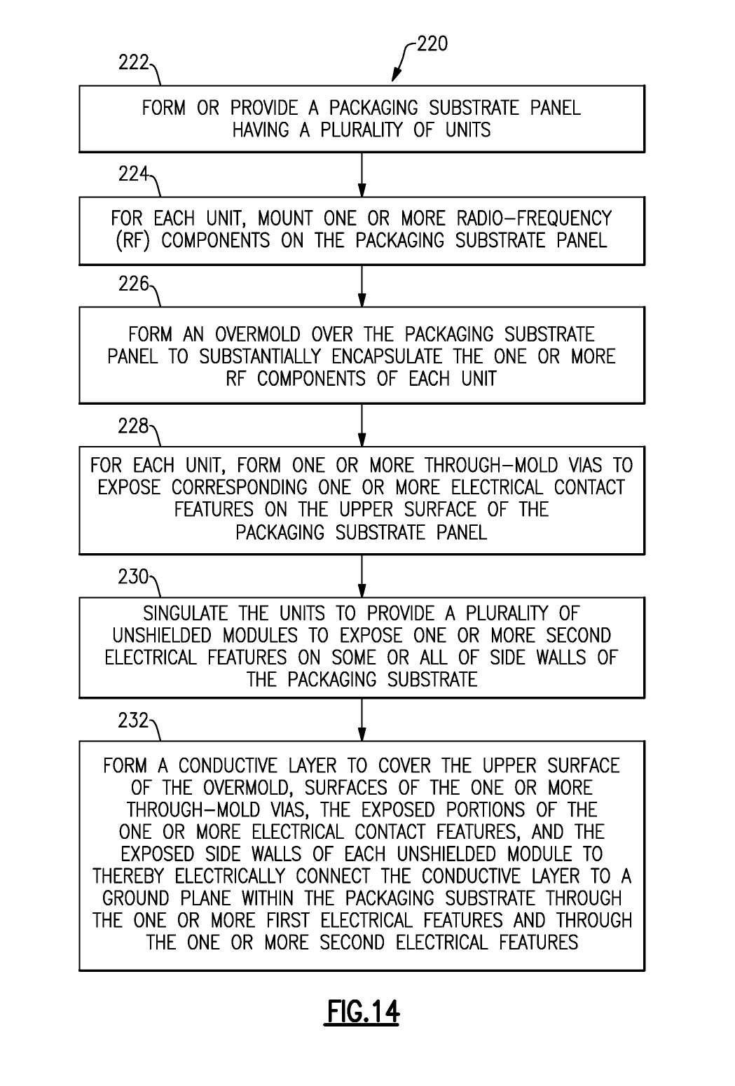

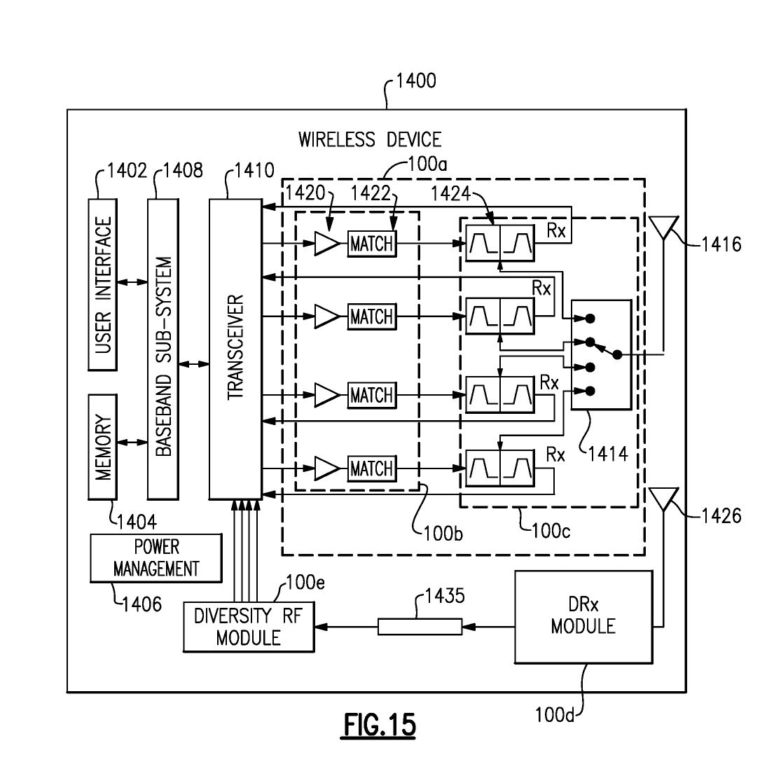

In some embodiments, a plurality of shielded RF modules having one or more features as described herein can be fabricated while in a panel format for some or all of various process steps. FIGS. 11A-11F show various example stages of a fabrication process that can be utilized to manufacture a plurality of shielded RF modules that do not have conductive side-wall layers. FIG. 13 shows an example process 200 that can be implemented to manufacture such shielded RF modules of FIGS. 11A-11F. FIGS. 12A-12F show various example stages of a fabrication process that can be utilized to manufacture a plurality of shielded RF modules that have conductive side walls. FIG. 14 shows an example process 220 that can be implemented to manufacture such shielded RF modules of FIGS. 12A-12F.

FIG. 11A shows a panel 130 having a plurality of units 131, where each unit is configured to become a packaging substrate 102 once singulated. Each unit 131 can include one or more contact pads 116 for respective TMV(s), and it is assumed that each of such contact pad(s) is electrically connected to a ground plane within the packaging substrate 102. In the process 200 of FIG. 13, such a panel having a plurality of units 131 can be formed or provided in block 202.

FIG. 11B shows a plurality of components 132, 134 mounted on the packaging substrate 102 of each unit 131 of the panel 130. Such components can include, for example, one or more die having respective integrated circuit(s), one or more surface mount devices (SMDs) such as passive components, or some combination thereof. Such components can be parts of an RF circuit assembly (e.g., 106 in FIG. 5). In the process 200 of FIG. 13, mounting of such one or more RF components on each unit of the packaging substrate panel can be achieved in block 204.

FIG. 11C shows that an overmold structure 136 can be formed over the packaging substrate panel 130 so as to cover each set of one or more components 132, 134 associated with the corresponding unit. In the process 200 of FIG. 13, formation of such an overmold over the panel 130 can be achieved in block 206.

FIG. 11D shows that one or more through-mold vias (TMVs) 110 can be formed through the overmold structure 136. Such TMVs can be formed to expose at least some of the corresponding contact pads 116. In some embodiments, such TMVs can be formed by, for example, laser drilling configured to burn through the overmold material and generally stop once the contact pads 116 are exposed. In the process 200 of FIG. 13, formation of such TMVs can be achieved in block 208.

FIG. 11E shows that a conductive layer 114 can be formed in a conformal manner so as to cover the upper surface of the overmold 136, the surface of each TMV, and the exposed portion of the corresponding contact pad 116. Accordingly, the conductive layer 114 on the upper surface of the overmold 136 can be electrically connected to the ground planes in the panel 130 through the respective conductive-material-coated TMVs. Such a conformal coating of conductive material can be applied by, for example, a deposition process such as a physical vapor deposition (PVD) process. In the process 200 of FIG. 13, formation of such conformal coating of conductive material can be achieved in block 210.

FIG. 11F shows that the assembly of FIG. 11E can be singulated into a plurality of shielded RF modules 100, each having the components 132, 134 mounted on the corresponding packaging substrate 102. As described herein, the conductive-material-coated TMVs provide an electrical connection between the conductive layer on the upper surface of the overmold of each module 100 and the contact pads (which are in turn electrically connected to a ground plane), to thereby provide shielding functionality (e.g., intra-module shielding and/or overall shielding for the module). As also described herein, such conductive-material-coated TMVs can replace shielding wirebonds, thereby eliminating process steps such as formation of shielding wirebonds, exposing of upper portions of such shielding wirebonds (e.g., utilizing micro-ablation technique), and formation of a conductive layer such as a painted metal layer to accommodate such shielding wirebonds. In the process 200 of FIG. 13, the foregoing singulation step can be achieved in block 212.

FIG. 12A shows a panel 140 having a plurality of units 141, where each unit is configured to become a packaging substrate 102 once singulated. Each unit 141 can include one or more contact pads 116 for respective TMV(s), and it is assumed that each of such contact pad(s) is electrically connected to a ground plane within the packaging substrate 102. In the process 220 of FIG. 14, such a panel having a plurality of units 141 can be formed or provided in block 222.

FIG. 12B shows a plurality of components 142, 144 mounted on the packaging substrate 102 of each unit 141 of the panel 140. Such components can include, for example, one or more die having respective integrated circuit(s), one or more surface mount devices (SMDs) such as passive components, or some combination thereof. Such components can be parts of an RF circuit assembly (e.g., 106 in FIG. 5). In the process 220 of FIG. 14, mounting of such one or more RF components on each unit of the packaging substrate panel can be achieved in block 224.

FIG. 12C shows that an overmold structure 146 can be formed over the packaging substrate panel 140 so as to cover each set of one or more components 142, 144 associated with the corresponding unit. In the process 220 of FIG. 14, formation of such an overmold over the panel 140 can be achieved in block 226.

FIG. 12D shows that one or more through-mold vias (TMVs) 110 can be formed through the overmold structure 146. Such TMVs can be formed to expose at least some of the corresponding contact pads 116. In some embodiments, such TMVs can be formed by, for example, laser drilling configured to burn through the overmold material and generally stop once the contact pads 116 are exposed. In the process 220 of FIG. 14, formation of such TMVs can be achieved in block 228.

FIG. 12E shows that the assembly of FIG. 12D can be singulated into a plurality of unshielded RF modules 150, each having the components 142, 144 mounted on the corresponding packaging substrate 102. In some embodiments, such a singulated form of each unshielded module 150 can expose one or more electrical contact features (e.g., similar to 34 in FIGS. 3 and 4) on some or all side walls of the packaging substrate 102. In the process 220 of FIG. 14, such a singulation step can be achieved in block 230.

FIG. 12F shows that the individual unshielded RF modules (150) of FIG. 12E can be processed further to form a form a conductive layer (e.g., a conformal metal layer) to cover the upper surface of the overmold, surface(s) of the one or more TMVs, exposed portion(s) of the one or more contact pads 116, and exposed side walls of each unshielded module 150. Accordingly, such a conformal metal layer can be electrically connected to the ground plane through the metal layer on the surface(s) of the TMV(s), as well as through the electrical contact feature(s) exposed at the side walls of the packaging substrate 102. In the process 220 of FIG. 14, such a conformal coating step can be achieved in block 232.

Examples related to processing of a plurality of individual singulated modules can be found in the above-mentioned U.S. Publication No. 2017/0221836.

As described herein, the foregoing examples of FIGS. 12 and 14 can provide a plurality of shielded RF modules, with each module having a conformal metal layer and one or more TMVs coated with the same conformal metal layer. Accordingly, such a configuration can provide intra-module shielding functionality as well as global shielding of the module itself.

In some implementations, a device and/or a circuit having one or more features described herein can be included in an RF electronic device such as a wireless device. In some embodiments, such a wireless device can include, for example, a cellular phone, a smart-phone, a hand-held wireless device with or without phone functionality, a wireless tablet, etc.

FIG. 15 depicts an example wireless device 1400 having one or more advantageous features described herein. In the example of FIG. 15, a shielded RF module having one or more features as described herein can be implemented in a number of ways. For example, a shielded RF module may be implemented as a front-end module (FEM) indicated as 100a. In another example, a shielded RF module may be implemented as a power amplifier module (PAM) indicated as 100b. In another example, a shielded RF module may be implemented as an antenna switch module (ASM) indicated as 100c. In another example, a shielded RF module may be implemented as a diversity receive (DRx) module indicated as 100d. It will be understood that a shielded RF module having one or more features as described herein can be implemented with other combinations of components.

Referring to FIG. 15, power amplifiers (PAs) 1420 can receive their respective RF signals from a transceiver 1410 that can be configured and operated to generate RF signals to be amplified and transmitted, and to process received signals. The transceiver 1410 is shown to interact with a baseband sub-system 1408 that is configured to provide conversion between data and/or voice signals suitable for a user and RF signals suitable for the transceiver 1410. The transceiver 1410 can also be in communication with a power management component 1406 that is configured to manage power for the operation of the wireless device 1400.

The baseband sub-system 1408 is shown to be connected to a user interface 1402 to facilitate various input and output of voice and/or data provided to and received from the user. The baseband sub-system 1408 can also be connected to a memory 1404 that is configured to store data and/or instructions to facilitate the operation of the wireless device, and/or to provide storage of information for the user.

In the example wireless device 1400, outputs of the PAs 1420 are shown to be matched (via respective match circuits 1422) and routed to their respective duplexers 1424. Such amplified and filtered signals can be routed to a primary antenna 1416 through an antenna switch 1414 for transmission. In some embodiments, the duplexers 1424 can allow transmit and receive operations to be performed simultaneously using a common antenna (e.g., primary antenna 1416). In FIG. 6, received signals are shown to be routed to “Rx” paths that can include, for example, a low-noise amplifier (LNA).

In the example of FIG. 15, the wireless device 1400 also includes the diversity antenna 1426 and the shielded DRx module 100d that receives signals from the diversity antenna 1426. The shielded DRx module 100d processes the received signals and transmits the processed signals via a transmission line 1435 to a diversity RF module 1411 that further processes the signal before feeding the signal to the transceiver 1410.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Description using the singular or plural number may also include the plural or singular number respectively. The word “or” in reference to a list of two or more items, that word covers all of the following interpretations of the word: any of the items in the list, all of the items in the list, and any combination of the items in the list.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While some embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

1. A shielded radio-frequency module comprising:
a packaging substrate having an upper side, a lower side, a ground plane, and one or more contact pads implemented on the upper side and electrically connected to the ground plane;
a radio-frequency circuit assembly implemented on either or both of the upper and lower sides of the packaging substrate;
an overmold implemented at least on the upper side of the packaging substrate to cover the one or more contact pads and some or all of the radio-frequency circuit assembly, the overmold defining an upper surface;
a conductive layer configured to cover some or all of the upper surface of the overmold; and
one or more through-mold features, each configured to provide an electrical connection between the conductive layer and the ground plane through the corresponding contact pad, to thereby provide shielding between a first location within the radio-frequency module and a second location relative to the radio-frequency module.

2. (canceled)

3. The shielded radio-frequency module of claim 1 wherein the one or more through-mold features include one or more through-mold vias.

4. The shielded radio-frequency module of claim 3 wherein the one or more through-mold vias include a plurality of through-mold vias implemented to laterally around some or all of the radio-frequency circuit assembly.

5. The shielded radio-frequency module of claim 4 wherein the plurality of through-mold vias are configured to provide shielding between the first location and the second location that is external to the radio-frequency module.

6. The shielded radio-frequency module of claim 1 wherein the shielding provided by the one or more through-mold features includes intra-module shielding between the first location and the second location that is also within the radio-frequency module.

7. (canceled)

8. The shielded radio-frequency module of claim 1 wherein the conductive layer is configured to cover substantially all of the upper surface of the overmold.

9. The shielded radio-frequency module of claim 8 wherein the radio-frequency module has a rectangular shaped footprint such that the upper surface of the overmold joins with four side walls defined by the radio-frequency module.

10. The shielded radio-frequency module of claim 9 wherein the conductive layer further covers at least some of each of the four side walls of the radio-frequency module.

11. The shielded radio-frequency module of claim 10 wherein the packaging substrate further includes a contact feature electrically connected to the ground plane and exposed on each of the four side walls, such that the conductive layer on the corresponding side wall is further electrically connected to the ground plane through the contact feature.

12. The shielded radio-frequency module of claim 11 wherein the conductive layer covering the upper surface of the overmold and the four side walls of the radio-frequency module is implemented as a conformal coating of conductive material.

13. The shielded radio-frequency module of claim 1 wherein each of the one or more through-mold features is an opening that extends from the upper surface of the overmold to the corresponding contact pad on the packaging substrate.

14. The shielded radio-frequency module of claim 13 wherein the electrical connection provided by the through-mold feature includes a conductive material that partially or fully fills the opening to electrically connect the conductive layer and the corresponding contact pad.

15. (canceled)

16. (canceled)

17. (canceled)

18. (canceled)

19. The shielded radio-frequency module of claim 1 further comprising a solder feature implemented over each of the one or more contact pads to raise a bottom portion of the corresponding through-mold feature away from the contact pad.

20. (canceled)

21. The shielded radio-frequency module of claim 1 wherein the radio-frequency circuit assembly is implemented on both of the upper side and the lower side of the packaging substrate.

22. The shielded radio-frequency module of claim 21 wherein the portion of the radio-frequency circuit assembly implemented on the lower side of the packaging substrate includes one or more die mounted to the lower side of the packaging substrate.

23. The shielded radio-frequency module of claim 22 further comprising a ball grid array implemented on the lower side of the packaging substrate to define an underside volume to accommodate the one or more die mounted to the lower side of the packaging substrate.

24. A method for manufacturing a plurality of shielded radio-frequency modules, the method comprising:
providing or forming a packaging substrate panel having a plurality of units, each unit having an upper side, a lower side, a ground plane, and one or more contact pads implemented on the upper side and electrically connected to the ground plane;
implementing a radio-frequency circuit assembly for each unit on either or both of the upper and lower sides of the packaging substrate panel;
forming an overmold on at least the upper side of the packaging substrate panel to cover the one or more contact pads and some or all of the radio-frequency circuit assembly of each unit, the overmold defining an upper surface; and
forming one or more openings through the overmold to expose at least a portion of each of the corresponding one or more contact pads, each opening configured to facilitate an electrical connection between the upper surface of the overmold and the corresponding contact pad.

25. (canceled)

26. The method of claim 24 further comprising forming a conductive layer on the upper surface of the overmold.

27. The method of claim 26 further comprising forming an electrical connection between the conductive layer on the upper surface of the overmold and the one or more contact pads through the one or more openings.

28. (canceled)

29. (canceled)

30. (canceled)

31. (canceled)

32. (canceled)

33. (canceled)

34. (canceled)

35. (canceled)

36. A wireless device comprising:
a circuit board configured to receive a plurality of components;
a transceiver implemented on the circuit board and configured to process radio-frequency signals; and
a shielded radio-frequency module implemented on the circuit board and in communication with the transceiver, the shielded radio-frequency module including a packaging substrate having an upper side, a lower side, a ground plane, and one or more contact pads implemented on the upper side and electrically connected to the ground plane; a radio-frequency circuit assembly implemented on either or both of the upper and lower sides of the packaging substrate; an overmold implemented at least on the upper side of the packaging substrate to cover the at least one contact pad and some or all of the radio-frequency circuit assembly, the overmold defining an upper surface; a conductive layer configured to cover some or all of the upper surface of the overmold; and one or more through-mold features, each configured to provide an electrical connection between the conductive layer and the ground plane through the corresponding contact pad, to thereby provide shielding between a first location within the radio-frequency module and a second location relative to the radio-frequency module.

37. (canceled)
